(19) United States
(12) Patent Application Publication
(10) Pub. No.: US 2010/0282298 A1
(43) Pub. Date: Nov. 11, 2010

(54) ELECTRONIC DEVICE FOR IMPROVING SOLAR CONVERSION EFFICIENCY

(76) Inventors: Chien-An Chen, Taipei City (TW); Zao-Shi Zheng, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/772,242

(22) Filed: May 3, 2010

(30) Foreign Application Priority Data
May 7, 2009 (TW) 098115205

(51) Int. Cl. H01L 31/052

(52) U.S. Cl. 136/246

(57) ABSTRACT

An electronic device for improving solar conversion efficiency includes a main body and a reflecting element. The main body includes an operation module and a solar panel. The solar panel is electrically connected with the operation module for converting light energy to electrical energy. The reflecting element is connected with the main body and corresponds to the solar panel for reflecting light to the solar panel.

### CROSS-REFERENCE TO RELATED APPLICATIONS

This Non-provisional application claims priority under 35 U.S.C. §119(a) on Patent Application No(s). 098115205 filed in Taiwan, Republic of China on May 7, 2009, the entire contents of which are hereby incorporated by reference.

### BACKGROUND OF THE INVENTION

1. Field of the Invention

This invention relates to an electronic device and, more particularly, to an electronic device for improving solar conversion efficiency.

2. Description of the Related Art

As portable electronic products are more and more popular, mobile phones, notebook computers, personal digital assistants (PDAs), cameras, and video cameras have gradually become electronic products taken by modern people with themselves.

The greatest difference between the portable electronic products and indoor plug-in electronic products is that a rechargeable battery is built in the portable electronic product and is charged via connecting a power socket with an external power supply. When the portable electronic product is used without connecting an external power source, the rechargeable battery provides the power needed by the portable electronic product.

If there is no external power source, using time of the portable electronic product is limited. Thus, a user has to take an external power supply with himself or herself to facilitate using the external power source when the power of the rechargeable battery exhausts. However, the external power source cannot be provided everywhere, and the present external power supply is too heavy to be taken by the user. Therefore, the user may fail to use the portable electronic product if the power of the rechargeable battery is exhausted and the usable external power source cannot be provided.

### BRIEF SUMMARY OF THE INVENTION

This invention provides an electronic device for improving solar conversion efficiency including a main body and a reflecting element. The main body includes an operation module and a solar panel. The solar panel is electrically connected with the operation module for converting light energy to electrical energy. The reflecting element is connected with the main body and corresponds to the solar panel for reflecting light to the solar panel.

The electronic device will convert light energy to electrical energy by the solar panel. Thereby, the electronic device is free from exhaust of power during operation. The electronic device uses the reflecting element to reflect incident light of surrounding environment to the solar panel thus to increase the light absorbing amount of the solar panel. In addition, the reflecting element can be rotated to a best reflecting angle according to the amount of the reflecting light for increasing the light-absorbing amount of the solar panel.

These and other features, aspects, and advantages of the present invention will become better understood with regard to the following description, appended claims, and accompanying drawings.

### BRIEF DESCRIPTION OF THE DRAWINGS

FIG. 1A is a schematic diagram showing an electronic device in an unused state according to a first embodiment of the invention;

FIG. 1B is a schematic diagram showing the electronic device in a using state according to the first embodiment of the invention;

FIG. 2A is a schematic diagram showing an electronic device in an unused state according to a second embodiment of the invention;

FIG. 2B is a schematic diagram showing the electronic device in a using state according to the second embodiment of the invention;

FIG. 3A is a first schematic diagram showing an electronic device in an unused state according to a third embodiment of the invention;

FIG. 3B is a first schematic diagram showing the electronic device in a using state according to the third embodiment of the invention;

FIG. 4A is a second schematic diagram showing the electronic device in the unused state according to the third embodiment of the invention;

FIG. 4B is a second schematic diagram showing the electronic device in the using state according to the third embodiment of the invention;

FIG. 5A is a schematic diagram showing an electronic device in an unused state according to a fourth embodiment of the invention;

FIG. 5B is a first schematic diagram showing the electronic device in a using state according to the fourth embodiment of the invention; and

FIG. 5C is a second schematic diagram showing the electronic device in the using state according to the fourth embodiment of the invention.

### DETAILED DESCRIPTION OF THE INVENTION

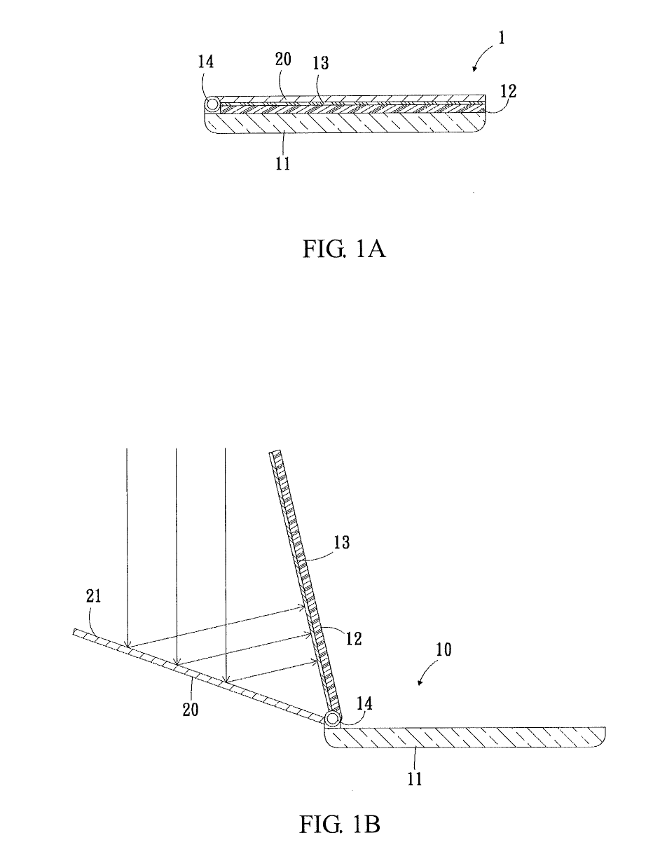

FIG. 1A and FIG. 1B are schematic diagrams showing an electronic device 1 for improving solar conversion efficiency according to a first embodiment of the invention. In the first embodiment, the electronic device 1 is a notebook computer. However, the invention is not limited thereto. The electronic device 1 may be a foldable mobile phone or other electronic devices. In the first embodiment of the invention, the electronic device 1 for improving solar conversion efficiency includes a main body 10 and a reflecting element 20.

The main body 10 mainly includes an operation module 11, a display module 12, a solar panel 13, and a hinge 14. The operation module 11 may include a keyboard, a power button, a touchpad and so on. A USB connector, a PCMCIA connector, or a SD card connector is disposed at edges of the operation module 11, thereby connecting different external devices. The display module 12 is connected with the operation module 11 for displaying images and operation results. In the embodiment, the hinge 14 is disposed at the operation module 11. The display module 12 is connected with the operation module 11 by the hinge 14 and rotates relative to the operation module 11. The display module 12 may be a liquid crystal display using a CCFL backlight module or an LED backlight module. However, the invention is not limited thereto. The solar panel 13 is disposed at a back surface of the display module 12. That is, the solar panel 13 is disposed at an outer surface of the display module 12 and is electrically connected with the operation module 11 for converting light energy to electrical energy, thereby providing power needed by operation of the operation module 11 and the display module 12.

The reflecting element 20 is movably connected with the main body 10 and corresponds to the solar panel 13. The reflecting element 20 has a reflecting plane 21 capable of reflecting the light to the solar panel 13. Incident and reflecting angles of the light is adjustable by changing the position of the reflecting element 20. In the embodiment, the reflecting element 20 is connected with the hinge 14 of the main body 10 to to be capable of rotating relative to the operation module 11 and the display module 12. In the embodiment, the reflecting element 20 may be a plane two-way mirror, and the area of the reflecting element 20 may be equal to or smaller than the surface area of the main body 10. However, the invention is not limited thereto. The reflecting element 20 may be a plane one-way mirror, and the area may be adjustable. In addition, the invention does not limit how the reflecting element 20 is connected with the hinge 14. Another hinge may be disposed at a side edge of the display module 12 to connect the reflecting element 20.

In FIG. 1A, the electronic device 1 is in an unused state. The display module 12 and the solar panel 13 are against the operation module 11, and the reflecting element 20 is stacked on the solar panel 13. The incident light of surrounding environment passes through the two-way mirror to the solar panel 13 so that the solar panel 13 converts the incident light to electrical energy and to store the energy in a battery. In FIG. 1B, the electronic device 1 is in a using state. A user lifts up the display module 12, the solar panel 13, and the reflecting element 20 to rotate them relative to the operation module 11 until the display module 12 is rotated to a best operation angle. Then, the reflecting element 20 is rotated relative to the operation module 11 and the display module 12 until the reflecting element 20 rotates to a reflecting position with a best reflecting angle. The reflecting element 20 and the solar panel 13 substantially form an acute angle. Therefore, when the user operates the operation module 11, the reflecting plane 21 of the reflecting element 20 reflects the incident light of the surrounding environment to the solar panel 13, thereby increasing the light-absorbing amount of the solar panel 13.

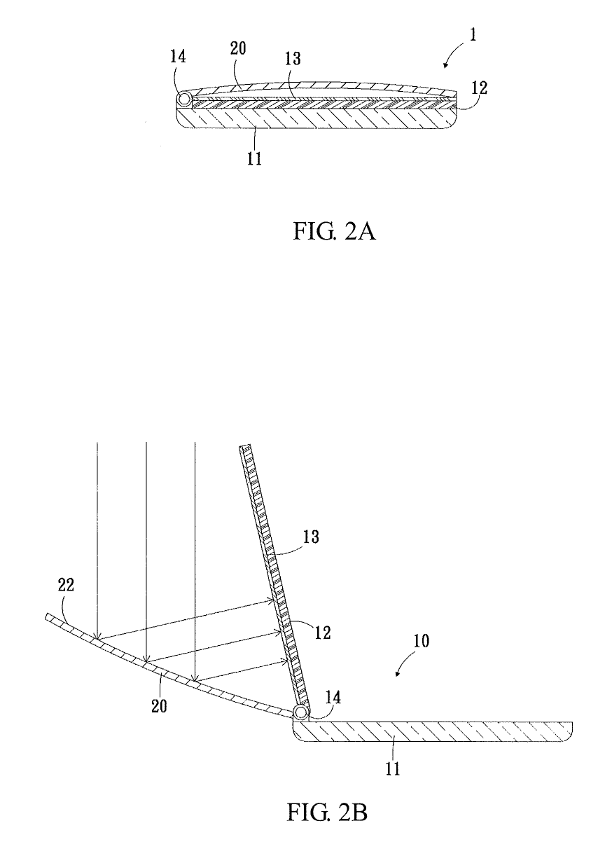

FIG. 2A and FIG. 2B are schematic diagrams showing an electronic device 1 for improving solar conversion efficiency according to a second embodiment of the invention. The difference between this embodiment and the first embodiment is that the structure of the reflecting element 20. In the second embodiment of the invention, the reflecting element 20 is a non-plane two-way mirror and has a reflecting curved surface 22 capable of reflecting light to the solar panel 13. When the reflecting area in the second embodiment is the same as that in the first embodiment, the non-plane reflecting element 20 reduces the length of the reflecting element 20. The reflecting element 20 occupies less space when the reflecting element 20 moves to the reflecting position. The operation mode and light reflecting mode of the second embodiment are the same as that in the first embodiment.

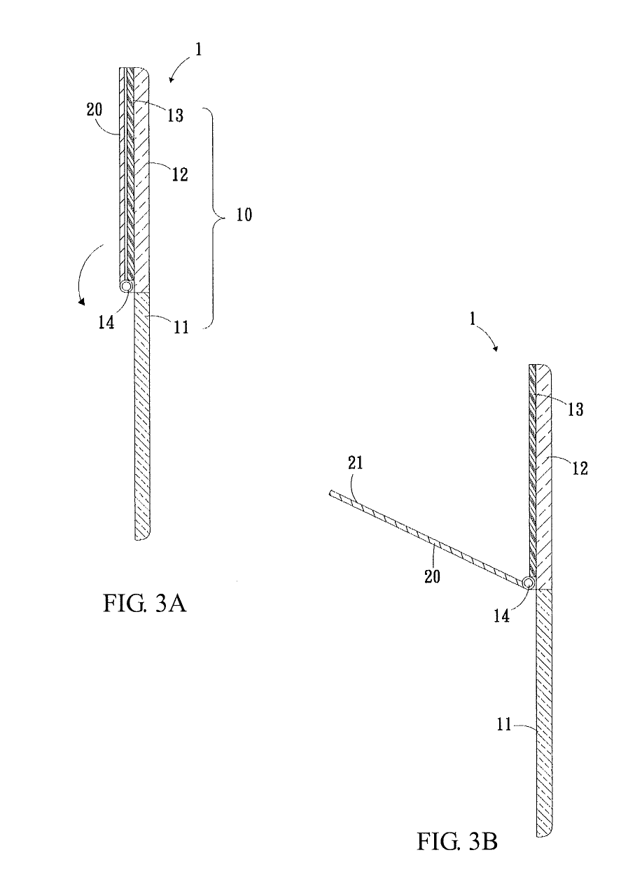

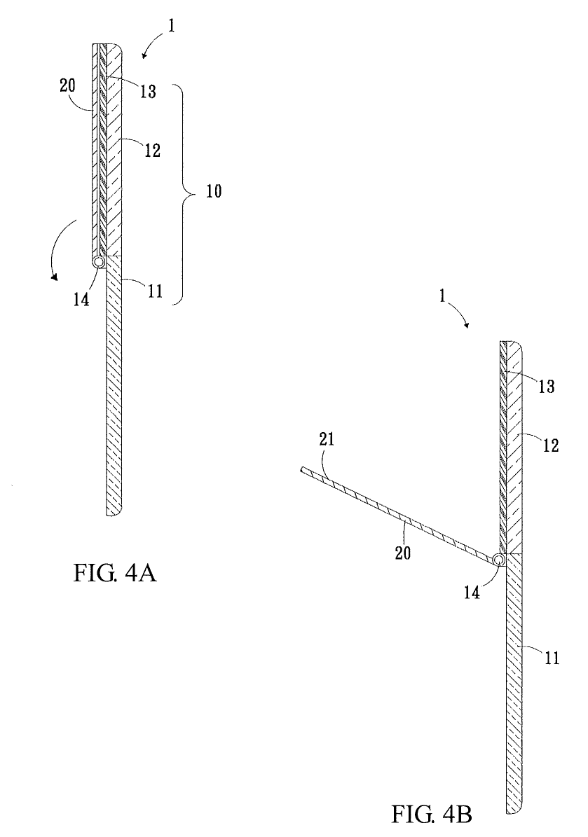

FIG. 3A, FIG. 3B, FIG. 4A, and FIG. 4B are schematic diagrams showing an electronic device 1 for improving solar conversion efficiency according to a third embodiment of the invention. The difference between this embodiment and the first embodiment is that the structure of the main body 10. In the third embodiment of the invention, the electronic device 1 may be a personal digital assistant (PDA), a media player, a PND, a digital camera, a digital video camera, or other electronic devices in a non-foldable mode. The operation module 11 and a casing of the display module 12 are integrally formed. In the embodiment, the reflecting element 20 is movably connected with the main body 10 and corresponds to the solar panel 13, and the reflecting element 20 is pivotally connected with a hinge 14 at a side edge of the display module 12, as shown in FIG. 3A, or be pivotally connected with the hinge 14 at a side edge of the operation module 11, as shown in FIG. 4A. The operation mode and light reflecting mode in this embodiment are the same as that in the first embodiment.

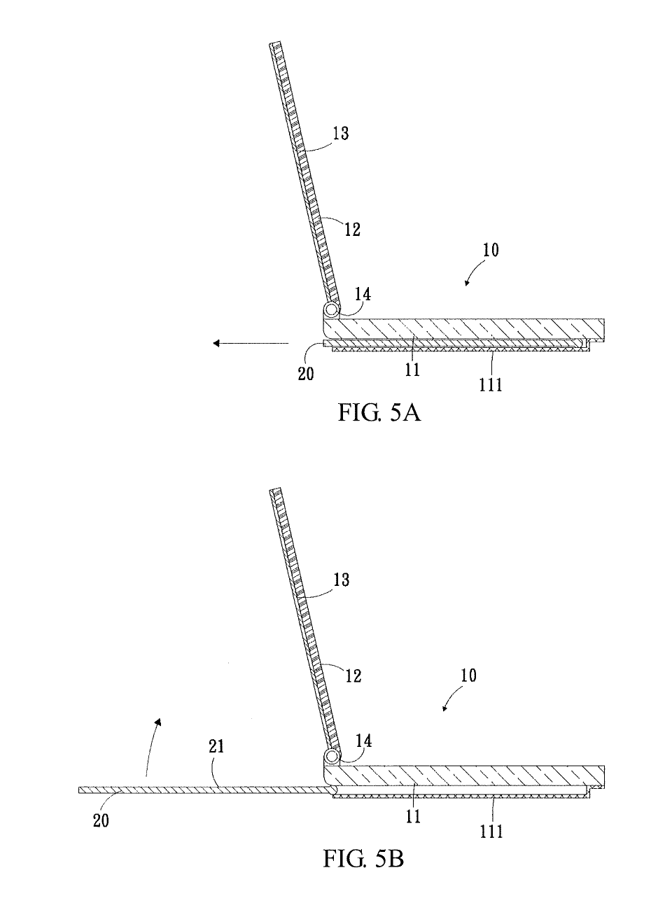

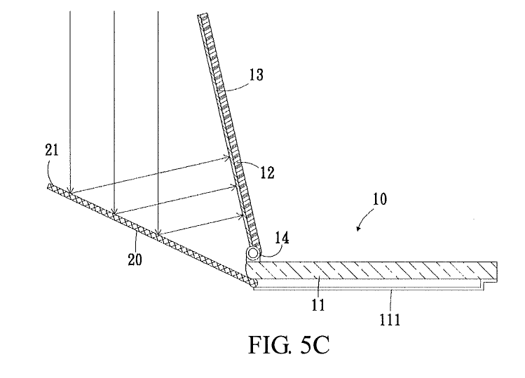

FIG. 5A, FIG. 5B, and FIG. 5C are schematic diagrams showing an electronic device 1 for improving solar conversion efficiency according to a fourth embodiment of the invention. The difference between this embodiment and the first embodiment is that the connection between the reflecting element 20 and the main body 10. In the embodiment, the bottom of the operation module 11 has a storage portion 111 for storing the reflecting element 20, and the reflecting element 20 moves in the storage portion 111. In use, the reflecting element 20 moves out of the storage portion 111 to expose at least one portion of the reflecting element 20 from the storage portion 111. Then, the reflecting element 20 is rotated relative to the operation module 11 and the display module 12 to adjust the incident and reflecting angles of the light until the reflecting element 20 rotates to a reflecting position with a best reflecting angle. Therefore, when the user operates the operation module 11, the reflecting plane 21 of the reflecting element 20 can reflect the incident light of the surrounding environment to the solar panel 13.

According to the above, the electronic device for improving solar conversion efficiency in the embodiments of the invention uses the solar panel to convert visible light to electrical energy thus to obtain electrical power and uses the reflecting element to reflect the incident light of the surrounding environment to the solar panel, thereby increasing the light-absorbing amount of the solar panel. In addition, the user may adjust the reflecting element to a best reflecting angle according to different incident light angles. Therefore, the light-absorbing amount of the solar panel can be increased in use.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. An electronic device for improving solar conversion efficiency, comprising:
a main body including:
an operation module; and
a solar panel electrically connected with the operation module for converting light energy to electrical energy; and
a reflecting element connected with the main body and corresponding to the solar panel for reflecting light to the solar panel.

2. The electronic device for improving solar conversion efficiency according to claim 1, wherein the main body comprises a display module pivotally connected with the operation module.

3. The electronic device for improving solar conversion efficiency according to claim 1, wherein the main body comprises a display module, and the operation module and a casing of the display module are integrally formed.

4. The electronic device for improving solar conversion efficiency according to claim 1, wherein the reflecting element comprises a one-way mirror.

5. The electronic device for improving solar conversion efficiency according to claim 1, wherein the reflecting element comprises a reflecting plane.

6. The electronic device for improving solar conversion efficiency according to claim 1, wherein the reflecting element comprises a reflecting curved surface.

7. The electronic device for improving solar conversion efficiency according to claim 1, wherein the reflecting element comprises a two-way mirror movably connected with the main body.

8. The electronic device for improving solar conversion efficiency according to claim 7, wherein when the two-way mirror moves to be stacked on the solar panel, the light passes through the two-way mirror to the solar panel.

9. The electronic device for improving solar conversion efficiency according to claim 1, wherein the operation module comprises a storage portion for storing the reflecting element.

10. The electronic device for improving solar conversion efficiency according to claim 9, wherein the reflecting element is capable of moving in the storage portion to expose at least one portion of the reflecting element from the storage portion.

11. The electronic device for improving solar conversion efficiency according to claim 1, wherein the reflecting element is movably connected with the main body to adjust incident and reflecting angles of the light.

12. The electronic device for improving solar conversion efficiency according to claim 1, wherein the reflecting element is pivotally connected with the main body to adjust incident and reflecting angles of the light.
